(19) United States
(12) Patent Application Publication
(10) Pub. No.: US 2026/0248030 A1
(43) Pub. Date: Aug. 20, 2026

(54) SEMICONDUCTOR DEVICE

(71) Applicants: Kabushiki Kaisha Toshiba, Kawasaki-shi, Kanagawa (JP); Toshiba Electronic Devices & Storage Corporation, Kawasaki-shi, Kanagawa (JP)

(72) Inventors: Tatsuya HIRAKAWA, Takasago Hyogo (JP); Eitaro MIYAKE, Tachikawa Tokyo (JP)

(21) Appl. No.: 19/161,887

(22) PCT Filed: Apr. 1, 2024
(86) PCT No.: PCT/JP2024/013493

§ 371 Date: Sep. 3, 2025

(30) Foreign Application Priority Data
Jul. 13, 2023 (JP) 2023-115349

(51) Int. Cl. H10W 76/12; H10D 62/832; H10D 80/20; H10W 76/01; H10W 76/18; H10W 76/47; H10W 76/63; H10W 76/67; H10W 90/00

(52) U.S. Cl. CPC H10W 76/12; H10D 62/8325; H10D 80/251; H10W 76/18; H10W 76/47; H10W 76/63; H10W 76/67; H10W 90/757; H10W 76/01

(57) ABSTRACT

A semiconductor device of an embodiment includes: an insulating substrate; a frame body; a first semiconductor chip including a first upper electrode, a first lower electrode, and a first semiconductor layer, the first semiconductor chip being provided on the insulating substrate; a first electrode terminal including a first flat plate portion and electrically connected to one of the first upper electrode and the first lower electrode; a second electrode terminal including a second flat plate portion facing the first flat plate portion and electrically connected to the other of the first upper electrode and the first lower electrode; a first resin member fixed to at least one of the first electrode terminal and the second electrode terminal and including a fitting portion fitted into the frame body, the fitting portion containing a first resin having a first volume resistivity and a first Young's modulus; and a second resin member provided between the first flat plate portion and the second flat plate portion and containing a second resin having a second volume resistivity greater than the first volume resistivity and a second Young's modulus greater than the first Young's modulus.

### TECHNICAL FIELD

Embodiments described herein relate generally to a semiconductor device.

### BACKGROUND ART

In a power semiconductor module, a power semiconductor chip is mounted on, for example, an insulating substrate. The power semiconductor chip is, for example, a metal oxide semiconductor field effect transistor (MOSFET).

When the inductance inside the power semiconductor module is large, for example, a surge voltage during switching increases. When the surge voltage during switching increases, for example, a problem arises in which a semiconductor chip is destroyed.

### CITATION LIST

### Patent Literature

Patent Literature 1: JP 6921794 B2

### SUMMARY OF THE INVENTION

### Problem to be Solved by the Invention

An object of the present invention is to provide a semiconductor device having reduced inductance.

### SOLUTION TO PROBLEM

### Means for Solving Problem

A semiconductor device includes: an insulating substrate; a frame body surrounding the insulating substrate; a first semiconductor chip including a first upper electrode, a first lower electrode, and a first semiconductor layer provided between the first upper electrode and the first lower electrode, the first semiconductor chip being provided on the insulating substrate; a first electrode terminal including a first flat plate portion and electrically connected to one of the first upper electrode and the first lower electrode; a second electrode terminal including a second flat plate portion facing the first flat plate portion and electrically connected to the other of the first upper electrode and the first lower electrode; a first resin member fixed to at least one of the first electrode terminal and the second electrode terminal and including a fitting portion fitted into the frame body, the fitting portion containing a first resin having a first volume resistivity and a first Young's modulus; and a second resin member provided between the first flat plate portion and the second flat plate portion and containing a second resin having a second volume resistivity greater than the first volume resistivity and a second Young's modulus greater than the first Young's modulus.

### BRIEF DESCRIPTION OF THE DRAWINGS

FIG. 1 is a schematic top view of a semiconductor device of a first embodiment.

FIG. 2 is a schematic cross-sectional view of the semiconductor device of the first embodiment.

FIG. 3 is a schematic top view of the semiconductor device of the first embodiment from which some members are removed.

FIG. 4 is an equivalent circuit diagram of the semiconductor device of the first embodiment.

FIG. 5 is a schematic top view of the semiconductor device of the first embodiment from which some members are removed.

FIG. 6 is a schematic top view of the semiconductor device of the first embodiment from which some members are removed.

FIG. 7 is a schematic cross-sectional view of the semiconductor device of the first embodiment.

FIG. 8 is a schematic cross-sectional view of the semiconductor device of the first embodiment.

FIG. 9 is a schematic cross-sectional view of the semiconductor device of the first embodiment.

FIG. 10 is a schematic cross-sectional view of the semiconductor device of the first embodiment.

FIG. 11 is a schematic cross-sectional view of the semiconductor device of the first embodiment during manufacturing.

FIG. 12 is a schematic cross-sectional view of the semiconductor device of the first embodiment during manufacturing.

FIG. 13 is a schematic top view of a semiconductor device of a second embodiment.

FIG. 14 is a schematic cross-sectional view of the semiconductor device of the second embodiment.

FIG. 15 is a schematic top view of the semiconductor device of the second embodiment from which some members are removed.

FIG. 16 is a schematic top view of the semiconductor device of the second embodiment from which some members are removed.

FIG. 17 is a schematic cross-sectional view of the semiconductor device of the second embodiment.

FIG. 18 is a schematic cross-sectional view of the semiconductor device of the second embodiment.

FIG. 19 is a schematic cross-sectional view of the semiconductor device of the second embodiment.

### EMDODIMENT(S) FOR CARRYING OUT THE INVENTION

In the present specification, the same or similar members are denoted by the same reference numerals, and redundant descriptions may be omitted.

In the present specification, in order to indicate a positional relationship of components and the like, an upward direction in the drawings may be described as “upper”, and a downward direction in the drawings may be described as “lower”. In the present specification, the terms “upper” and “lower” do not necessarily indicate directions relative to the direction of gravity.

### First Embodiment

A semiconductor device of a first embodiment includes: an insulating substrate; a frame body surrounding the insulating substrate; a first semiconductor chip including a first upper electrode, a first lower electrode, and a first semiconductor layer provided between the first upper electrode and the first lower electrode, the first semiconductor chip being provided on the insulating substrate; a first electrode terminal including a first flat plate portion and electrically connected to one of the first upper electrode and the first lower electrode; a second electrode terminal including a second flat plate portion facing the first flat plate portion and electrically connected to the other of the first upper electrode and the first lower electrode; a first resin member fixed to at least one of the first electrode terminal and the second electrode terminal and including a fitting portion fitted into the frame body, the fitting portion containing a first resin having a first volume resistivity and a first Young's modulus; and a second resin member provided between the first flat plate portion and the second flat plate portion and containing a second resin having a second volume resistivity greater than the first volume resistivity and a second Young's modulus greater than the first Young's modulus.

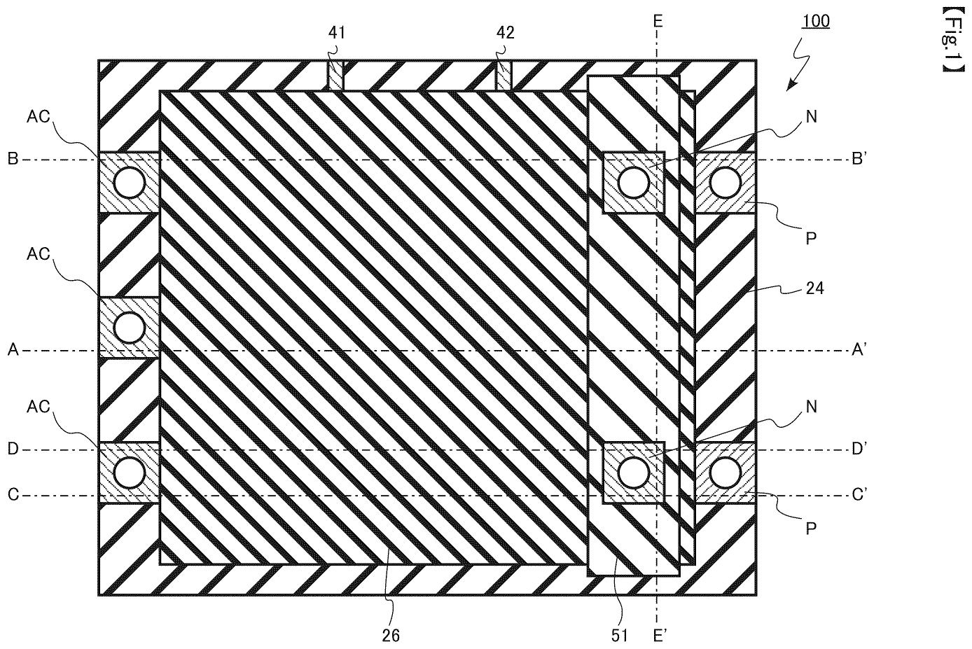

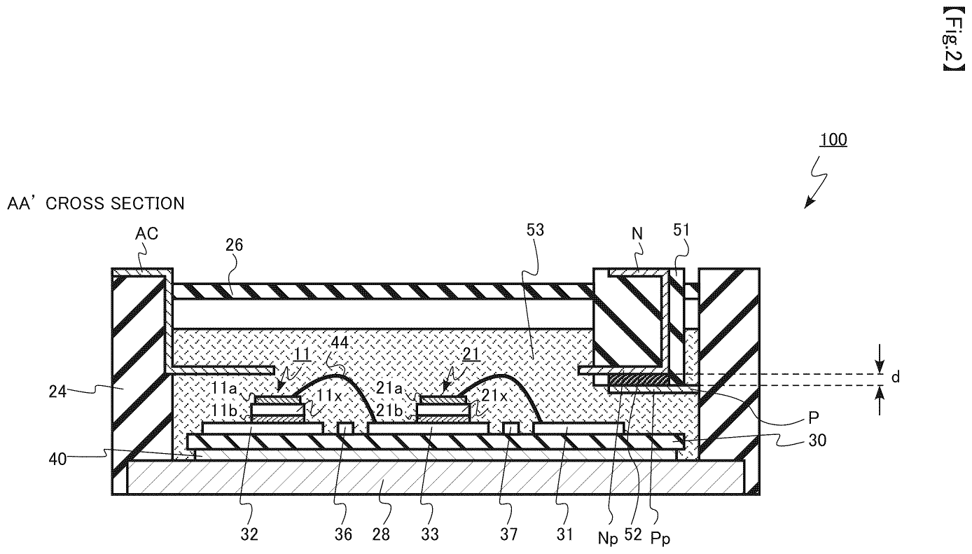

FIG. 1 is a schematic top view of the semiconductor device of the first embodiment. FIGS. 2, 7, 8, 9, and 10 are schematic cross-sectional views of the semiconductor device of the first embodiment.

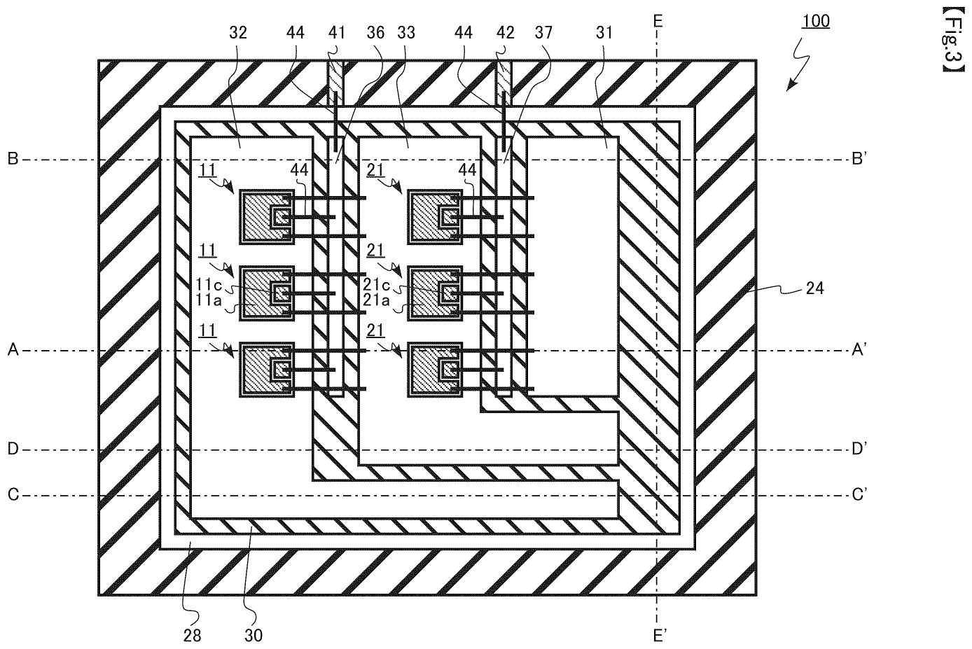

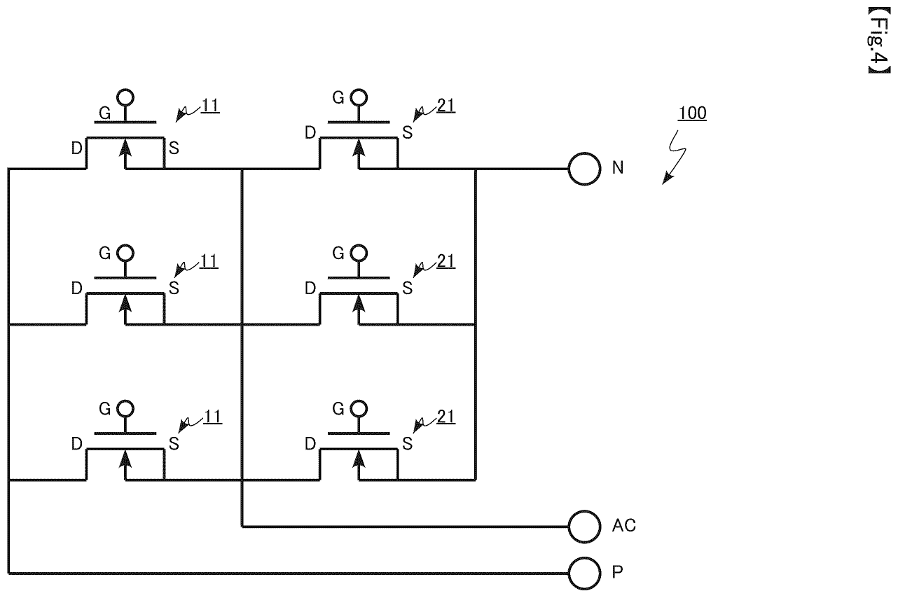

FIGS. 3, 5, and 6 are schematic top views of the semiconductor device of the first embodiment from which some members are removed. FIG. 4 is an equivalent circuit diagram of the semiconductor device of the first embodiment.

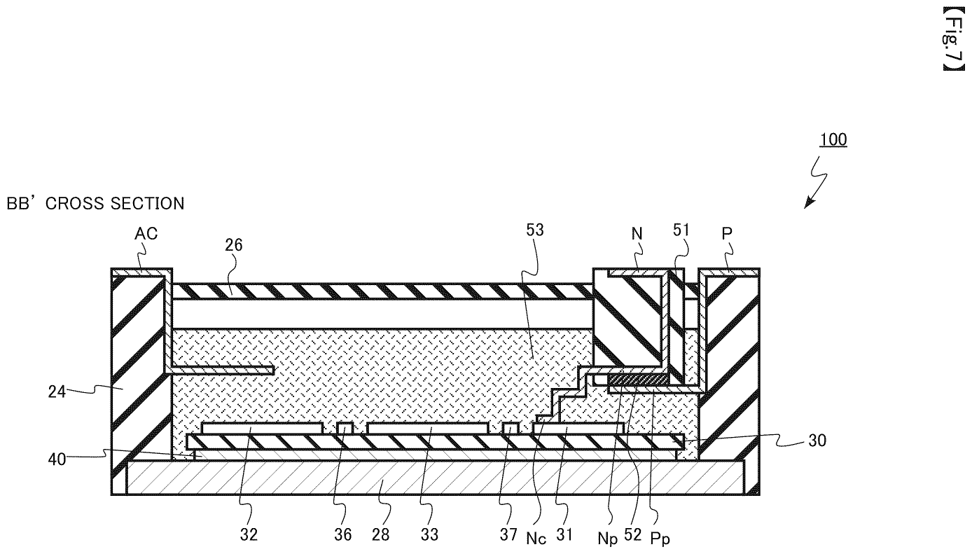

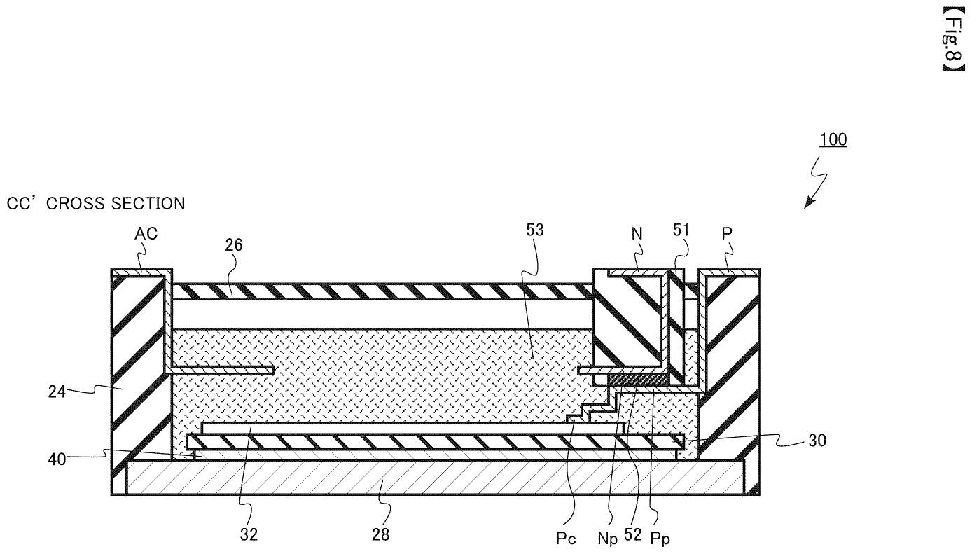

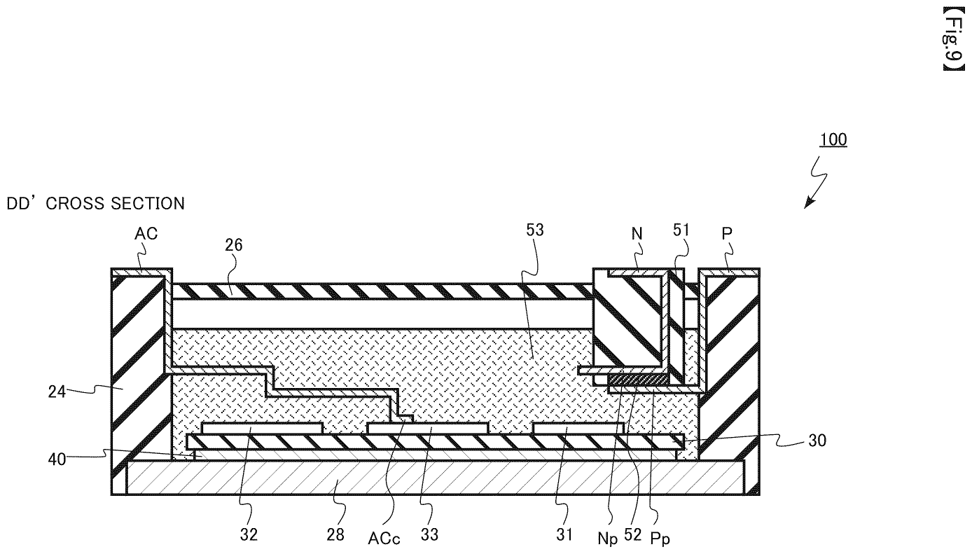

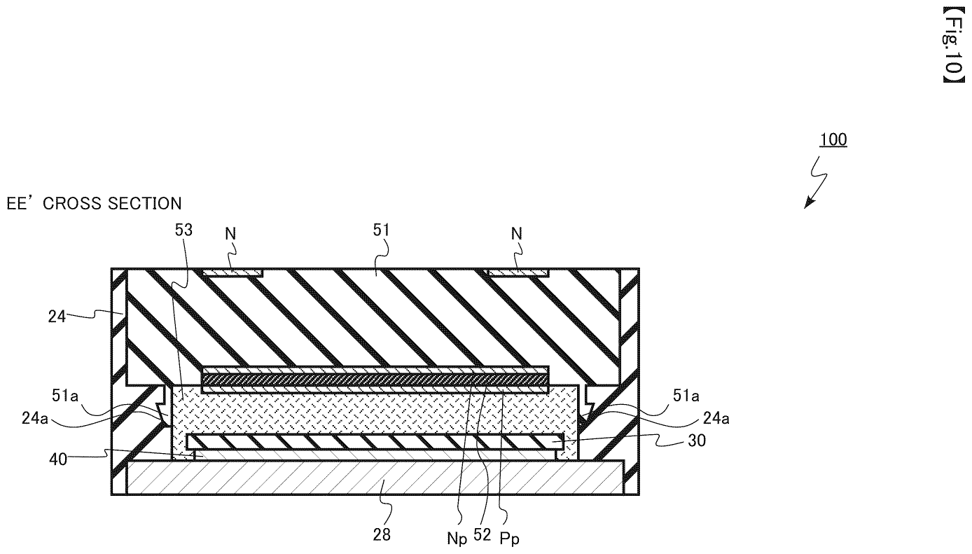

FIG. 2 is a cross section taken along line AA′ of FIGS. 1, 3, 5, and 6. FIG. 7 is a cross section taken along line BB′ of FIGS. 1, 3, 5, and 6. FIG. 8 is a cross section taken along line CC′ of FIGS. 1, 3, 5, and 6. FIG. 9 is a cross section taken along line DD′ of FIGS. 1, 3, 5, and 6. FIG. 10 is a cross section taken along line EE′ of FIGS. 1, 3, 5, and 6.

The semiconductor device of the first embodiment is a power semiconductor module 100. As illustrated in FIG. 4, the power semiconductor module 100 of the first embodiment is a so-called “2-in-1” type module capable of forming a half-bridge circuit with a single module. In the power semiconductor module 100, three half-bridge units are connected in parallel. For example, a three-phase inverter circuit can be configured by using three power semiconductor modules 100 of the first embodiment.

As illustrated in FIG. 4, the power semiconductor module 100 includes a negative terminal N (first electrode terminal), a positive terminal P (second electrode terminal), an AC output terminal AC, a plurality of high-side MOSFETS 11 (first semiconductor chips), and a plurality of low-side MOSFETs 21 (second semiconductor chips).

The plurality of high-side MOSFETs 11 are connected in parallel. The plurality of low-side MOSFETs 21 are connected in parallel. The plurality of high-side MOSFETs 11 and the plurality of low-side MOSFETs 21 are connected in series.

FIGS. 1 to 10 illustrate a case where the number of high-side MOSFETs 11 is three and the number of low-side MOSFETs 21 is three.

As illustrated in FIGS. 1 to 10, the power semiconductor module 100 of the first embodiment includes a negative terminal N (first electrode terminal), a positive terminal P (second electrode terminal), an AC output terminal AC, a plurality of high-side MOSFETs 11 (first semiconductor chips), a plurality of low-side MOSFETs 21 (second semiconductor chips), a resin case 24 (frame body), a lid 26, a metal base 28, an insulating substrate 30, a first metal layer 31, a second metal layer 32, a third metal layer 33, a first gate metal layer 36, a second gate metal layer 37, a back surface metal layer 40, a first gate terminal 41, a second gate terminal 42, a bonding wire 44, an electrode support member 51 (first resin member), a spacer member 52 (second resin member), and a sealing member 53 (third resin member).

Each of the plurality of high-side MOSFETs 11 (first semiconductor chips) includes a first source electrode 11a (first upper electrode), a first drain electrode 11b (first lower electrode), a first gate electrode 11c, and a first silicon carbide layer 11x (first semiconductor layer).

Each of the plurality of low-side MOSFETs 21 (second semiconductor chips) includes a second source electrode 21a (second upper electrode), a second drain electrode 21b (second lower electrode), a second gate electrode 21c, and a second silicon carbide layer 21x (second semiconductor layer).

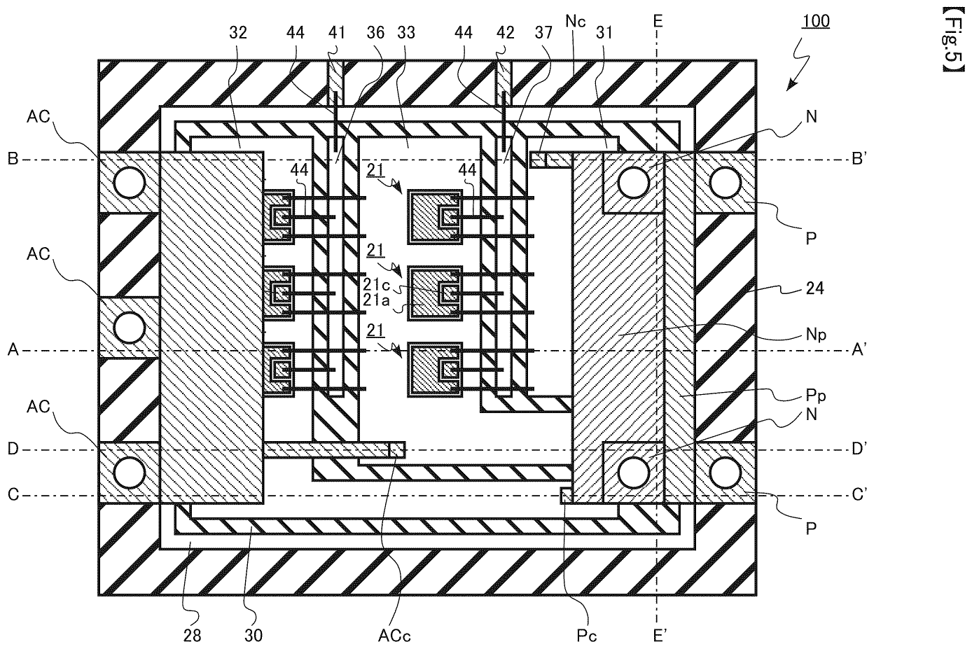

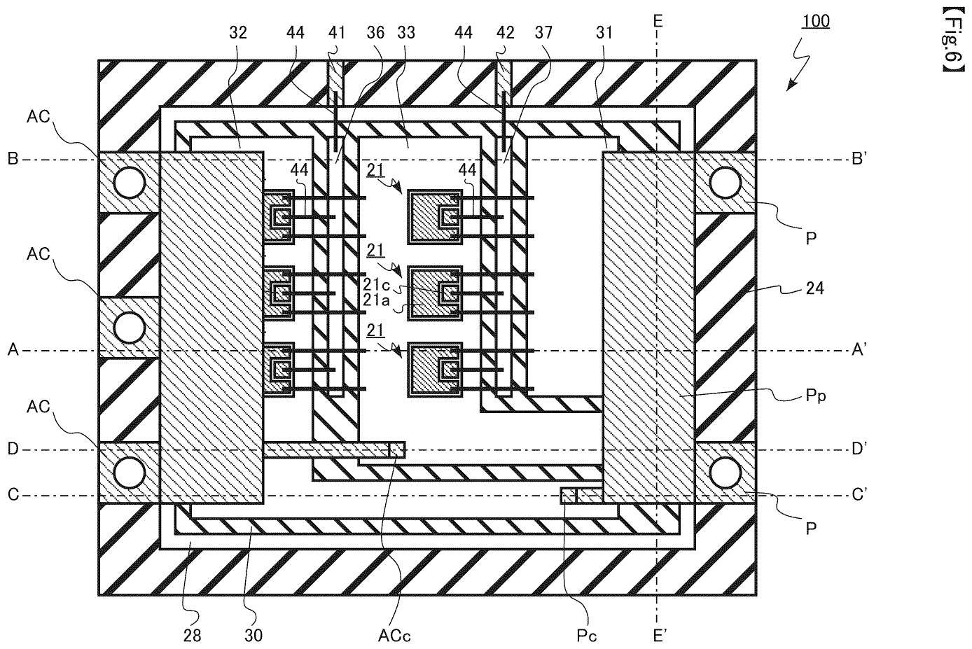

FIG. 3 is a top view of a state in which the negative terminal N (first electrode terminal), the positive terminal P (second electrode terminal), the AC output terminal AC, the lid 26, the electrode support member 51 (first resin member), the spacer member 52 (second resin member), and the sealing member 53 are removed from the power semiconductor module 100. FIG. 5 is a top view of a state in which the lid 26, the electrode support member 51 (first resin member), the spacer member 52 (second resin member), and the sealing member 53 are removed from the power semiconductor module 100. FIG. 6 is a top view of a state in which the negative terminal N (first electrode terminal), the lid 26, the electrode support member 51 (first resin member), the spacer member 52 (second resin member), and the sealing member 53 are removed from the power semiconductor module 100.

The metal base 28 is, for example, copper. For example, when the power semiconductor module 100 is mounted on a product, a heat sink (not illustrated) is connected to a back surface of the metal base 28.

The insulating substrate 30 is provided on the metal base 28. The insulating substrate 30 is provided between the metal base 28 and the high-side MOSFET 11. The insulating substrate 30 is provided between the metal base 28 and the low-side MOSFET 21.

The insulating substrate 30 has a function of electrically separating the metal base 28 from the high-side MOSFET 11, and the metal base 28 from the low-side MOSFET 21.

The insulating substrate 30 is, for example, ceramic. The insulating substrate 30 is, for example, aluminum oxide, aluminum nitride, or silicon nitride.

The first metal layer 31, the second metal layer 32, the third metal layer 33, the first gate metal layer 36, and the second gate metal layer 37 are provided on a surface of the insulating substrate 30. The first metal layer 31, the second metal layer 32, the third metal layer 33, the first gate metal layer 36, and the second gate metal layer 37 are, for example, copper.

The back surface metal layer 40 is provided on a back surface of the insulating substrate 30. The back surface metal layer 40 is, for example, copper. The back surface metal layer 40 is bonded to the metal base 28 using, for example, a solder layer or a silver nanoparticle layer (not illustrated).

The resin case 24 is provided around the metal base 28 and the insulating substrate 30. The resin case 24 is an example of the frame body. A part of resin case 24 is provided on the metal base 28.

The resin case 24 has a function of protecting the high-side MOSFET 11, the low-side MOSFET 21, and the insulating substrate 30.

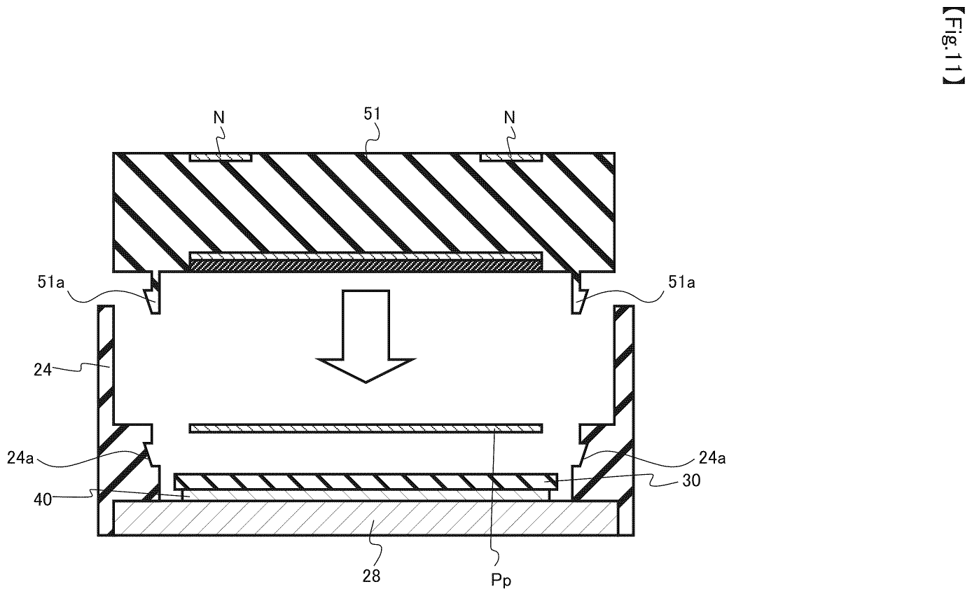

As illustrated in FIGS. 10 and 11, a notch portion 24a for fitting the fitting portion 51a of the electrode support member 51 is provided on the inner side face of the resin case 24.

The resin case 24 contains a fourth resin. The resin case 24 is formed of, for example, a fourth resin.

The fourth resin has a fourth volume resistivity and a fourth Young's modulus. The fourth resin is, for example, a polyphenylene sulfide resin (PPS resin). The resin case 24 is formed of, for example, a polyphenylene sulfide resin (PPS resin).

The lid 26 is provided on an upper portion of the resin case 24. The lid 26 has a function of protecting the high-side MOSFET 11, the low-side MOSFET 21, and the insulating substrate 30.

The plurality of high-side MOSFETs 11 are provided on the second metal layer 32. Each of the plurality of high-side MOSFETs 11 includes a first source electrode 11a, a first drain electrode 11b, a first gate electrode 11c, and a first silicon carbide layer 11x. The first source electrode 11a is an example of the first upper electrode.

The first drain electrode 11b is an example of the first lower electrode. The first silicon carbide layer 11x is an example of the first semiconductor layer.

The first silicon carbide layer 11x is provided between the first source electrode 11a and the first drain electrode 11b. The high-side MOSFET 11 is a vertical MOSFET.

The first source electrode 11a is electrically connected to the third metal layer 33. The first source electrode 11a and the third metal layer 33 are electrically connected using, for example, the bonding wire 44.

The first source electrode 11a is electrically connected to the negative terminal N via the third metal layer 33, the low-side MOSFET 21, and the first metal layer 31.

The first drain electrode 11b is electrically connected to the second metal layer 32. The first drain electrode 11b is electrically connected to the second metal layer 32 using, for example, a solder layer or a silver nanoparticle layer (not illustrated).

The first drain electrode 11b is electrically connected to the positive terminal P via the second metal layer 32.

The plurality of high-side MOSFETs 11 are arranged in a direction parallel to the insulating substrate 30.

The plurality of low-side MOSFETs 21 are provided on the third metal layer 33. Each of the plurality of low-side MOSFETs 21 includes the second source electrode 21a, the second drain electrode 21b, the second gate electrode 21c, and the second silicon carbide layer 21x. The second source electrode 21a is an example of the second upper electrode. The second drain electrode 21b is an example of the second lower electrode. The second silicon carbide layer 21x is an example of the second semiconductor layer.

The second silicon carbide layer 21x is provided between the second source electrode 21a and the second drain electrode 21b. The low-side MOSFET 21 is a vertical MOSFET.

### The Second Source Electrode 21a Is Electrically

connected to the first metal layer 31. The second source electrode 21a and the first metal layer 31 are electrically connected using, for example, the bonding wire 44. The second drain electrode 21b is electrically connected to the third metal layer 33. The second drain electrode 21b is electrically connected to the third metal layer 33 using, for example, a solder layer or a silver nanoparticle layer (not illustrated).

The plurality of low-side MOSFETs 21 are arranged in a direction parallel to the insulating substrate 30.

The sealing member 53 is filled in the resin case 24. The sealing member 53 is surrounded by the resin case 24. The sealing member 53 covers the high-side MOSFET 11, the low-side MOSFET 21, and the insulating substrate 30.

The sealing member 53 has a function of protecting the high-side MOSFET 11, the low-side MOSFET 21, and the insulating substrate 30. In addition, the sealing member 53 has a function of insulating the high-side MOSFET 11, the low-side MOSFET 21, and the insulating substrate 30.

The sealing member 53 contains a third resin. The sealing member 53 is formed of, for example, a third resin.

The third resin has a third volume resistivity and a third Young's modulus. The third resin is, for example, a silicone gel. As the third resin, for example, other resins such as a polyimide resin can be applied.

The negative terminal N is provided on an upper side of the insulating substrate 30. The negative terminal N is an example of the first electrode terminal.

The negative terminal N has a first flat plate portion Np and a first connection portion Nc. The negative terminal N has a wiring connection hole.

The negative terminal N is electrically connected to the first metal layer 31 using the first connection portion Nc. The first metal layer 31 and the first connection portion Nc are connected using, for example, ultrasonic metal bonding. In addition, the first metal layer 31 and the first connection portion Nc are connected using, for example, a solder layer or a silver nanoparticle layer (not illustrated).

For example, a negative voltage is applied to the negative terminal N from the outside. The negative terminal N is formed of a metal. The negative terminal N is, for example, copper.

The positive terminal P is provided on the upper side of the insulating substrate 30. The positive terminal P is an example of the second electrode terminal.

The positive terminal P has a second flat plate portion Pp and a second connection portion Pc. The positive terminal P has a wiring connection hole.

The positive terminal P is electrically connected to the second metal layer 32 using the second connection portion Pc. The second metal layer 32 and the second connection portion Pc are connected using, for example, ultrasonic metal bonding. In addition, the second metal layer 32 and the second connection portion Pc are connected using, for example, a solder layer or a silver nanoparticle layer (not illustrated).

The second flat plate portion Pp faces the first flat plate portion Np. The second flat plate portion Pp and the first flat plate portion Np are parallel to each other.

A distance between the first flat plate portion Np and the insulating substrate 30 is, for example, greater than a distance between the second flat plate portion Pp and the insulating substrate 30. The second flat plate portion Pp is provided, for example, between the first flat plate portion Np and the insulating substrate 30.

A distance (d in FIG. 2) between the first flat plate portion Np and the second flat plate portion Pp is, for example, equal to or more than 0.2 mm and equal to or less than 2 mm.

For example, a positive voltage is applied to the positive terminal P from the outside. The positive terminal P is formed of a metal. The positive terminal P is, for example, copper.

The AC output terminal AC is provided on the upper side of the insulating substrate 30. The AC output terminal AC is provided on the same side of the insulating substrate 30 as the positive terminal P and the negative terminal N.

The AC output terminal AC includes a third connection portion ACc and a wiring connection hole.

The AC output terminal AC is electrically connected to the third metal layer 33 by using the third connection portion ACc. The third metal layer 33 and the third connection portion ACc are connected using, for example, ultrasonic metal bonding. In addition, the third metal layer 33 and the third connection portion ACc are connected using, for example, a solder layer or a silver nanoparticle layer (not illustrated).

The AC output terminal AC outputs an output current of the half-bridge circuit. The AC output terminal AC is formed of a metal. The AC output terminal AC is, for example, copper.

The first gate terminal 41 is electrically connected to the first gate electrode 11c of the high-side MOSFET 11. The first gate terminal 41 is electrically connected to the first gate electrode 11c by using, for example, the first gate metal layer 36 and the bonding wire 44.

The second gate terminal 42 is electrically connected to the second gate electrode 21c of the low-side MOSFET 21. The second gate terminal 42 is electrically connected to the second gate electrode 21c by using, for example, the second gate metal layer 37 and the bonding wire 44.

The first metal layer 31 is provided on the insulating substrate 30. The first metal layer 31 is electrically connected to the negative terminal N. The first metal layer 31 is electrically connected to the second source electrode 21a of the low-side MOSFET 21.

The second metal layer 32 is provided on the insulating substrate 30. The second metal layer 32 is electrically connected to the positive terminal P.

The second metal layer 32 is provided between the high-side MOSFET 11 and the insulating substrate 30. The second metal layer 32 is electrically connected to the first drain electrode 11b of the high-side MOSFET 11.

The third metal layer 33 is provided on the insulating substrate 30. The third metal layer 33 is electrically connected to the AC output terminal AC.

The third metal layer 33 is provided between the low-side MOSFET 21 and the insulating substrate 30. The third metal layer 33 is electrically connected to the second drain electrode 21b of the low-side MOSFET 21.

The electrode support member 51 supports, for example, the negative terminal N. The electrode support member 51 is fixed to, for example, the negative terminal N. The negative terminal N and the electrode support member 51 are integrated using, for example, insert molding. The electrode support member 51 may be fixed to, for example, the positive terminal P.

The electrode support member 51 includes the fitting portion 51a. The fitting portion 51a has a protruding shape.

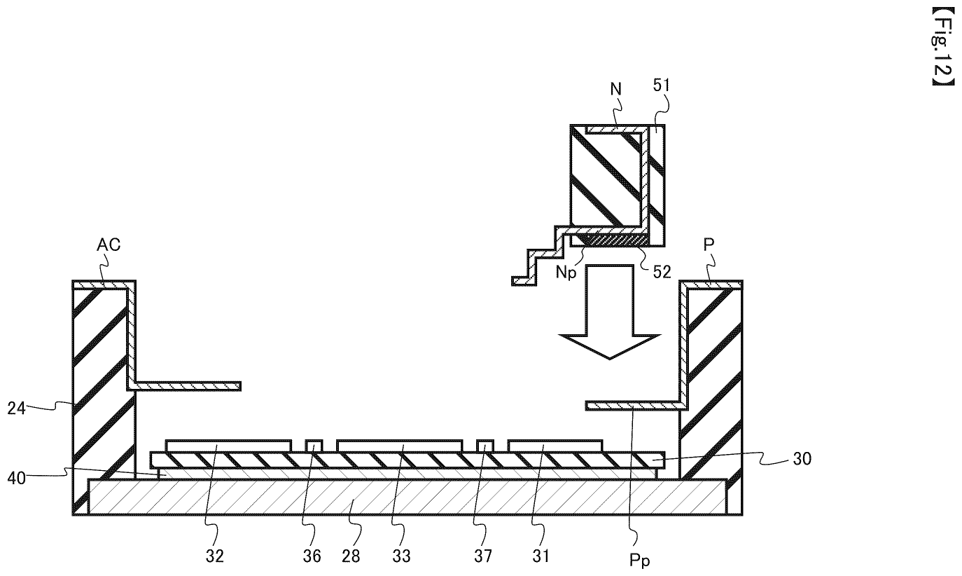

FIGS. 11 and 12 are schematic cross-sectional views of the semiconductor device of the first embodiment during manufacturing. FIGS. 11 and 12 are cross-sectional views illustrating a step of fixing the electrode support member 51 to the resin case 24.

FIG. 11 illustrates a cross section corresponding to FIG. 10. FIG. 12 illustrates a cross section corresponding to FIG. 7.

As illustrated in FIGS. 10, 11, and 12, the electrode support member 51 is fixed to the resin case 24 by fitting the fitting portion 51a into the notch portion 24a provided on the inner side face of the resin case 24.

The fitting portion 51a contains a first resin having a first volume resistivity and a first Young's modulus. The fitting portion 51a is formed of, for example, a first resin. The entire electrode support member 51 may be formed of a first resin.

The first resin is, for example, a polyamide resin (PA resin) or a polybutylene terephthalate resin (PBT resin). The fitting portion 51a is formed of, for example, a polyamide resin (PA) or a polybutylene terephthalate resin (PBT).

The spacer member 52 is provided between the first flat plate portion Np of the negative terminal N and the second flat plate portion Pp of the positive terminal P. The spacer member 52 is fixed to, for example, the negative terminal N. The negative terminal N, the spacer member 52, and the electrode support member 51 are integrated using, for example, insert molding. The spacer member 52 may be fixed to, for example, the positive terminal P.

The spacer member 52 is in contact with, for example, the first flat plate portion Np. The spacer member 52 is in contact with, for example, the second flat plate portion Pp. For example, the spacer member 52 may be separated from the first flat plate portion Np or the second flat plate portion Pp.

The spacer member 52 has a function of electrically insulating the negative terminal N and the positive terminal P from each other. The spacer member 52 has a function of electrically insulating the first flat plate portion Np and the second flat plate portion Pp.

A thickness of the spacer member 52 is, for example, equal to or more than 0.2 mm and equal to or less than 2 mm.

The spacer member 52 contains a second resin having a second volume resistivity and a second Young's modulus. The spacer member 52 is formed of, for example, a second resin.

The second volume resistivity is greater than the first volume resistivity. In addition, the second Young's modulus is greater than the first Young's modulus.

The second resin is, for example, a polyphenylene sulfide resin (PPS resin). The spacer member 52 is formed of, for example, a polyphenylene sulfide resin (PPS resin).

The first resin is, for example, a polyamide resin, and the second resin is, for example, a polyphenylene sulfide resin having a greater volume resistivity and a greater Young's modulus than the polyamide resin. The first resin is, for example, a polybutylene terephthalate resin, and the second resin is, for example, a polyphenylene sulfide resin having a greater volume resistivity and a greater Young's modulus than the polybutylene terephthalate resin.

The third resin contained in the sealing member 53 has a third volume resistivity and a third Young's modulus. The third volume resistivity is, for example, greater than the second volume resistivity. In addition, the third Young's modulus is, for example, lower than the first Young's modulus.

When the first resin is, for example, a polyamide resin and the second resin is, for example, a polyphenylene sulfide resin, the third resin is, for example, a silicone gel having a greater volume resistivity than the polyphenylene sulfide resin and a lower Young's modulus than the polyamide resin.

In addition, when the first resin is, for example, a polybutylene terephthalate resin and the second resin is, for example, a polyphenylene sulfide resin, the third resin is, for example, a silicone gel having a greater volume resistivity than the polyphenylene sulfide resin and a lower Young's modulus than the polybutylene terephthalate resin.

The fourth resin contained in the resin case 24 has a fourth volume resistivity and a fourth Young's modulus. The fourth volume resistivity is, for example, greater than the first volume resistivity. In addition, the fourth Young's modulus is, for example, greater than the first Young's modulus.

The fourth resin contained in the resin case 24 is, for example, the same as the second resin contained in the spacer member 52.

The first resin is, for example, a polyamide resin, and the fourth resin is, for example, a polyphenylene sulfide resin having a greater volume resistivity and a greater Young's modulus than the polyamide resin. When the first resin is, for example, a polybutylene terephthalate resin, the fourth resin is, for example, a polyphenylene sulfide resin having a greater volume resistivity and a greater Young's modulus than the polybutylene terephthalate resin.

Next, a function and effect of the semiconductor device of the first embodiment will be described.

When the inductance inside the power semiconductor module is large, for example, a surge voltage during switching increases. When the surge voltage during switching increases, for example, a problem arises in which a semiconductor chip is destroyed. Therefore, it is desirable to reduce the inductance inside the power semiconductor module.

The inductance of wiring includes self-inductance due to self-induction and mutual inductance due to mutual induction. The inductance of wiring is the sum of the self-inductance and the mutual inductance.

For example, in the power semiconductor module 100 of the first embodiment, the inductance between the negative terminal N and the positive terminal P is the sum of the self-inductances of the negative terminal N and the positive terminal P and the mutual inductance associated with the mutual induction of the negative terminal N and the positive terminal P.

In the power semiconductor module 100 of the first embodiment, the first flat plate portion Np is provided on the negative terminal N, and the second flat plate portion Pp is provided on the positive terminal P. The first flat plate portion Np and the second flat plate portion Pp face each other in parallel.

In the first flat plate portion Np and the second flat plate portion Pp, the directions of the flowing currents are opposite to each other. Therefore, the mutual inductance functions in a direction to offset the self-inductance. Accordingly, the inductance between the negative terminal N and the positive terminal P is reduced. Therefore, the inductance inside the power semiconductor module 100 is reduced.

As the distance between the first flat plate portion Np and the second flat plate portion Pp decreases, the inductance between the negative terminal N and the positive terminal P can be reduced, and the inductance inside the power semiconductor module 100 can be reduced. However, when the distance between the first flat plate portion Np and the second flat plate portion Pp decreases, electrical insulation between the negative terminal N and the positive terminal P cannot be secured, resulting in a short circuit between the negative terminal N and the positive terminal P, which may cause the power semiconductor module 100 to be destroyed.

In the power semiconductor module 100 of the first embodiment, by providing the spacer member 52 between the first flat plate portion Np and the second flat plate portion Pp, electrical insulation between the negative terminal N and the positive terminal P is secured. The resin constituting the spacer member 52 is desired to have a high volume resistivity.

In the power semiconductor module 100 of the first embodiment, the negative terminal N is attached by fitting the electrode support member 51 to which the negative terminal N is fixed into the resin case 24. By attaching the negative terminal N using the electrode support member 51, the negative terminal N can be easily attached. In addition, high mechanical strength of the power semiconductor module 100 and high electrical insulation of the power semiconductor module 100 are secured by attaching using the electrode support member 51.

The electrode support member 51 is fixed to the resin case 24 by fitting the fitting portion 51a provided on the electrode support member 51 into the notch portion 24a provided on the inner side face of the resin case 24. At this time, when the elastic deformation amount of the fitting portion 51a having the protrusion shape is not large, the fitting portion 51a may be damaged. Therefore, the resin constituting the fitting portion 51a is desired to have a low Young's modulus.

In the power semiconductor module 100 of the first embodiment, the fitting portion 51a contains a first resin having a first volume resistivity and a first Young's modulus. In addition, the spacer member 52 contains a second resin having a second volume resistivity and a second Young's modulus.

The second volume resistivity is greater than the first volume resistivity. In addition, the second Young's modulus is greater than the first Young's modulus. That is, the spacer member 52 has a volume resistivity greater than that of the fitting portion 51a, and has high electrical insulation. The fitting portion 51a has a Young's modulus lower than that of the spacer member 52, and has a greater amount of elastic deformation.

Since the spacer member 52 has high electrical insulation, the distance between the first flat plate portion Np and the second flat plate portion Pp can be reduced. Accordingly, the inductance inside the power semiconductor module 100 can be reduced.

In addition, a greater amount of elastic deformation of the fitting portion 51a of the electrode support member 51 facilitates attachment of the negative terminal N to the resin case 24. In addition, damage to the fitting portion 51a is suppressed, and the manufacturing yield of the power semiconductor module 100 is improved.

According to the power semiconductor module 100 of the first embodiment, it is possible to achieve both a reduction in inductance inside the power semiconductor module 100 and a high manufacturing yield of the power semiconductor module 100.

From the viewpoint of achieving both a reduction in inductance and a high manufacturing yield, it is preferable that the first resin contained in the fitting portion 51a is a polyamide resin, and the second resin contained in the spacer member 52 is a polyphenylene sulfide resin.

From the viewpoint of achieving both a reduction in inductance and a manufacturing yield, it is preferable that the first resin contained in the fitting portion 51a is a polybutylene terephthalate resin, and the second resin contained in the spacer member 52 is a polyphenylene sulfide resin.

From the viewpoint of easily securing electrical insulation in the power semiconductor module 100, it is preferable that the sealing member 53 contains a third resin having a third volume resistivity greater than the second volume resistivity and a third Young's modulus lower than the first Young's modulus.

From the viewpoint of easily securing mechanical strength and electrical insulation of the power semiconductor module 100, it is preferable that the resin case 24 contains a fourth resin having a fourth volume resistivity greater than the first volume resistivity and a fourth Young's modulus greater than the first Young's modulus.

From the viewpoint of reducing the inductance inside the power semiconductor module 100, the distance (d in FIG. 2) between the first flat plate portion Np and the second flat plate portion Pp is preferably equal to or less than 2 mm, more preferably equal to or less than 1. 5 mm, and still more preferably equal to or less than 1 mm.

As described above, according to the first embodiment, it is possible to provide a semiconductor device having reduced inductance.

### Second Embodiment

A semiconductor device of a second embodiment differs from the semiconductor device of the first embodiment in that a second semiconductor chip is not provided.

Hereinafter, some descriptions of contents overlapping with the first embodiment may be omitted.

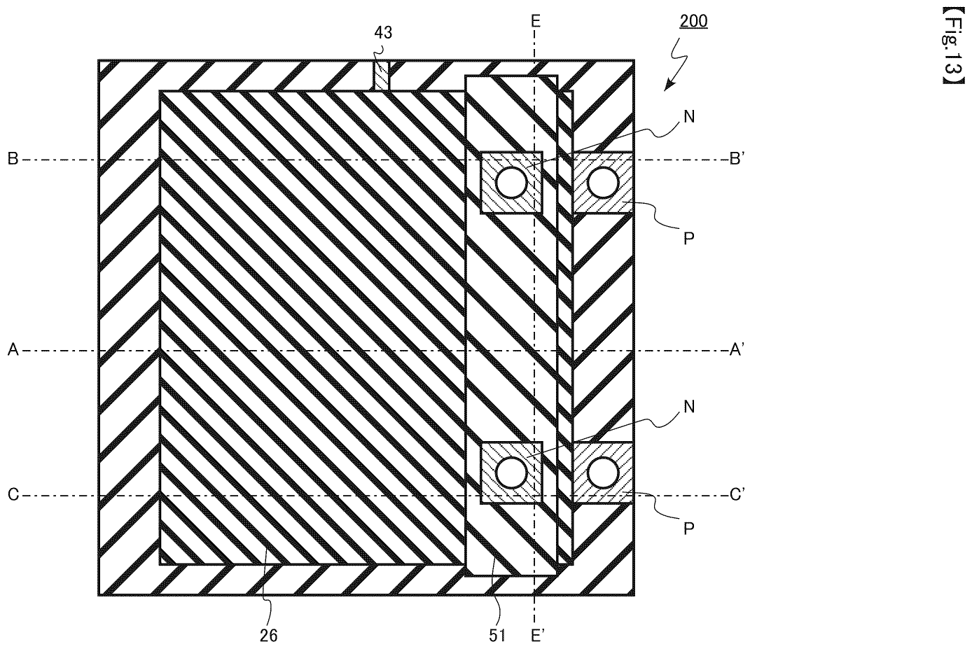

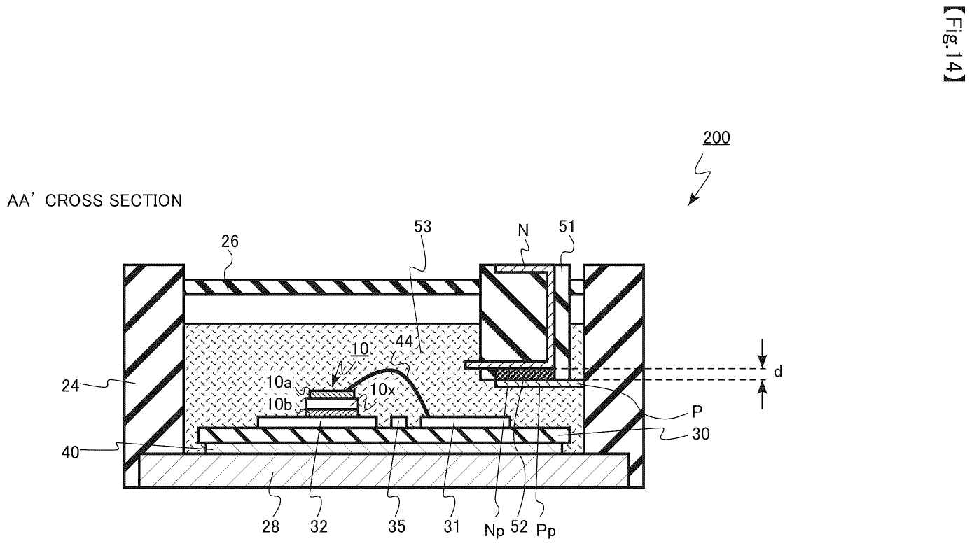

FIG. 13 is a schematic top view of the semiconductor device of the second embodiment. FIGS. 14, 17, 18, and 19 are schematic cross-sectional views of the semiconductor device of the second embodiment.

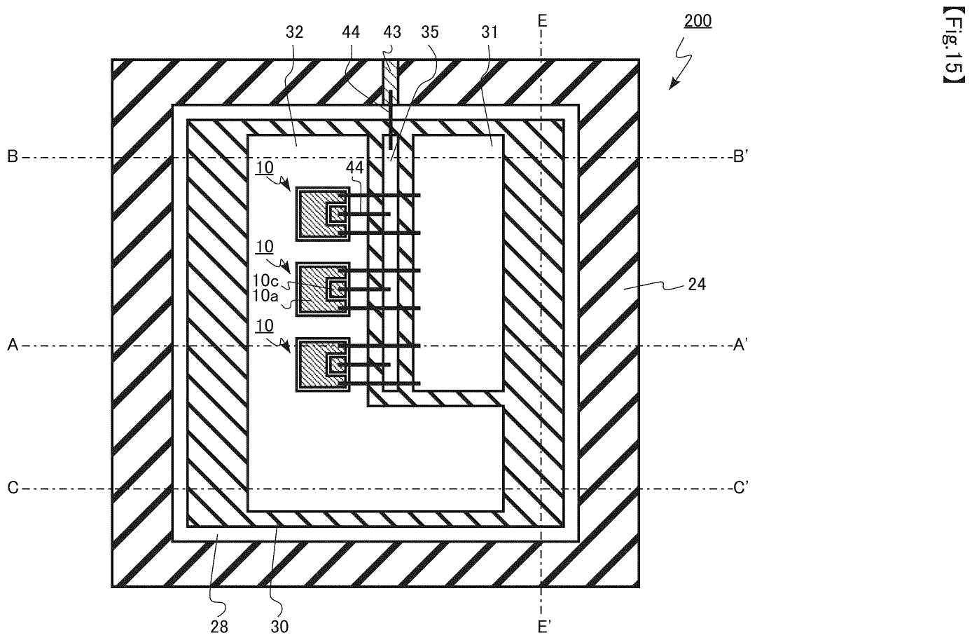

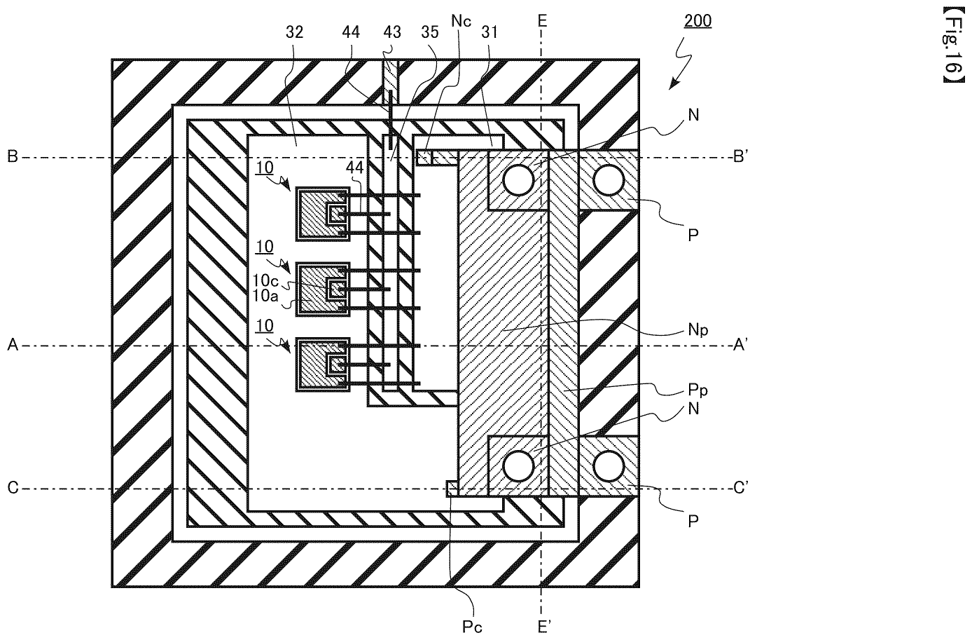

FIGS. 15 and 16 are schematic top views of the semiconductor device of the second embodiment from which some members are removed.

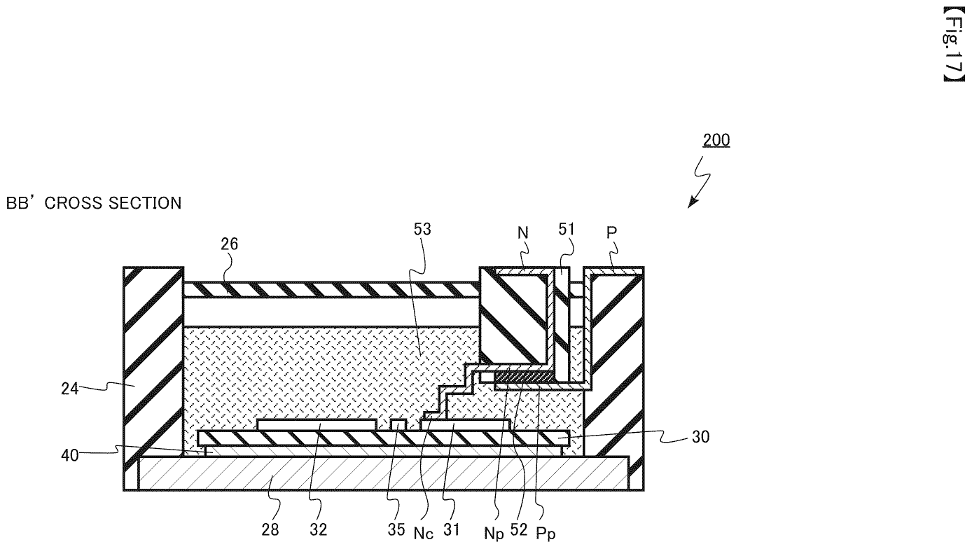

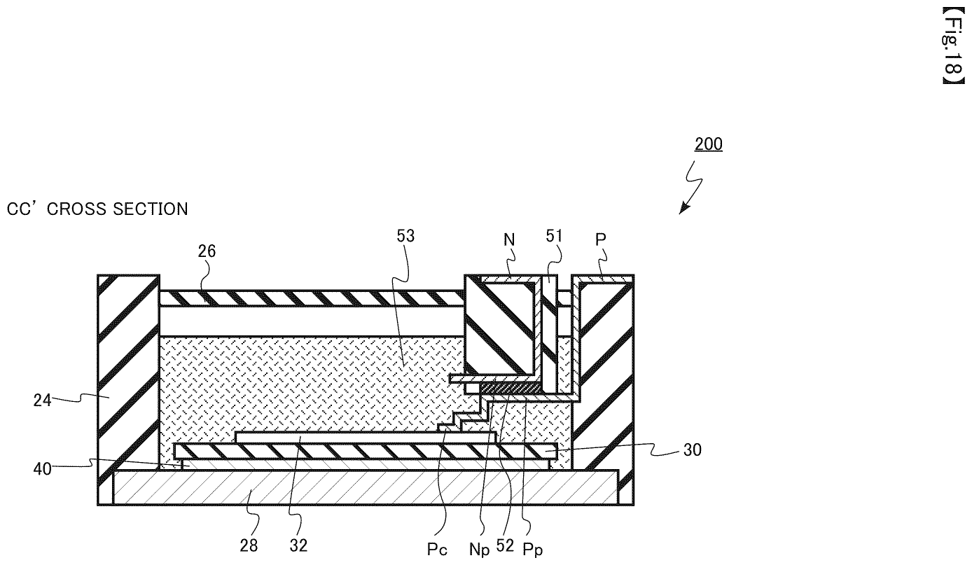

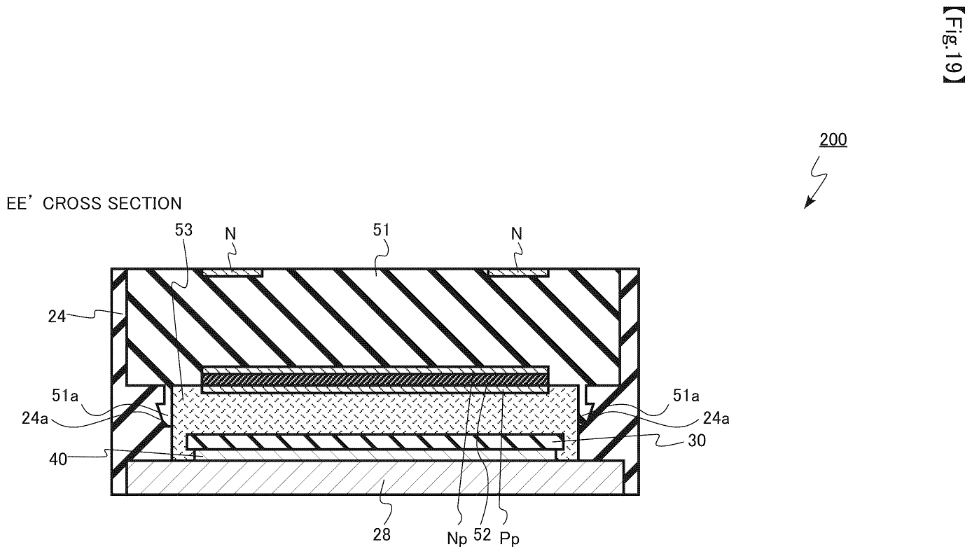

FIG. 14 is a cross section taken along line AA′ of FIGS. 13, 15, and 16. FIG. 17 is a cross section taken along line BB′ of FIGS. 13, 15, and 16. FIG. 18 is a cross section taken along line CC′ of FIGS. 13, 15, and 16. FIG. 19 is a cross section taken along line EE′ of FIGS. 13, 15, and 16.

The semiconductor device of the second embodiment is a power semiconductor module 200. The power semiconductor module 200 of the second embodiment is a so-called “1-in-1” type module. In the power semiconductor module 200, three MOSFETs are connected in parallel.

A plurality of MOSFETs 10 (first semiconductor chips) are connected in parallel.

FIGS. 13 to 19 illustrate a case where the number of MOSFETs 10 is three.

As illustrated in FIGS. 13 to 19, the power semiconductor module 200 of the second embodiment includes a negative terminal N (first electrode terminal), a positive terminal P (second electrode terminal), a plurality of MOSFETs 10 (first semiconductor chips), a resin case 24 (frame body), a lid 26, a metal base 28, an insulating substrate 30, a first metal layer 31, a second metal layer 32, a gate metal layer 35, a back surface metal layer 40, a gate terminal 43, a bonding wire 44, an electrode support member 51 (first resin member), a spacer member 52 (second resin member), and a sealing member 53 (third resin member).

Each of the plurality of MOSFETs 10 (first semiconductor chips) includes a source electrode 10a (first upper electrode), a drain electrode 10b (first lower electrode), a gate electrode 10c, and a silicon carbide layer 10x (first semiconductor layer).

FIG. 15 is a top view of a state in which the negative terminal N (first electrode terminal), the positive terminal P (second electrode terminal), the lid 26, the electrode support member 51 (first resin member), the spacer member 52 (second resin member), and the sealing member 53 are removed from the power semiconductor module 200. FIG. 16 is a top view of a state in which the lid 26, the electrode support member 51 (first resin member), the spacer member 52 (second resin member), and the sealing member 53 are removed from the power semiconductor module 100.

The first metal layer 31, the second metal layer 32, and the gate metal layer 35 are provided on a surface of the insulating substrate 30.

As illustrated in FIG. 19, a notch portion 24a for fitting the fitting portion 51a of the electrode support member 51 is provided on the inner side face of the resin case 24.

The resin case 24 contains a fourth resin. The resin case 24 is formed of, for example, a fourth resin.

The fourth resin has a fourth volume resistivity and a fourth Young's modulus. The fourth resin is, for example, a polyphenylene sulfide resin. The resin case 24 is formed of, for example, a polyphenylene sulfide resin.

The plurality of MOSFETs 10 are provided on the second metal layer 32. Each of the plurality of MOSFETs 10 includes the source electrode 10a, the drain electrode 10b, the gate electrode 10c, and the silicon carbide layer 10x. The source electrode 10a is an example of the first upper electrode. The drain electrode 10b is an example of the first lower electrode. The silicon carbide layer 10x is an example of the first semiconductor layer.

The silicon carbide layer 10x is provided between the source electrode 10a and the drain electrode 10b. The MOSFET 10 is a vertical MOSFET.

The source electrode 10a is electrically connected to the first metal layer 31. The source electrode 10a and the first metal layer 31 are electrically connected using, for example, the bonding wire 44.

The source electrode 10a is connected to the negative terminal N via the first metal layer 31.

The drain electrode 10b is electrically connected to the second metal layer 32. The drain electrode 10b and the drain electrode 10b are connected to the positive terminal P via the second metal layer 32.

The plurality of MOSFETs 10 are arranged in a direction parallel to the insulating substrate 30.

The sealing member 53 is filled in the resin case 24. The sealing member 53 is surrounded by the resin case 24. The sealing member 53 covers the MOSFET 10 and the insulating substrate 30.

The sealing member 53 contains a third resin. The sealing member 53 is formed of, for example, a third resin.

The third resin has a third volume resistivity and a third Young's modulus. The third resin is, for example, a silicone gel. As the third resin, for example, other resins such as a polyimide resin can be applied.

The negative terminal N is provided on an upper side of the insulating substrate 30. The negative terminal N is an example of the first electrode terminal.

The negative terminal N has a first flat plate portion Np and a first connection portion Nc. The negative terminal N has a wiring connection hole.

The negative terminal N is electrically connected to the first metal layer 31 using the first connection portion Nc.

For example, a negative voltage is applied to the negative terminal N from the outside.

The positive terminal P is provided on the upper side of the insulating substrate 30. The positive terminal P is an example of the second electrode terminal.

The positive terminal P has a second flat plate portion Pp and a second connection portion Pc. The positive terminal P has a wiring connection hole.

The positive terminal P is electrically connected to the second metal layer 32 using the second connection portion Pc.

The second flat plate portion Pp faces the first flat plate portion Np. The second flat plate portion Pp and the first flat plate portion Np are parallel to each other.

A distance between the first flat plate portion Np and the insulating substrate 30 is, for example, greater than a distance between the second flat plate portion Pp and the insulating substrate 30. The second flat plate portion Pp is provided, for example, between the first flat plate portion Np and the insulating substrate 30.

A distance (d in FIG. 14) between the first flat plate portion Np and the second flat plate portion Pp is, for example, equal to or more than 0.2 mm and equal to or less than 2 mm.

For example, a positive voltage is applied to the positive terminal P from the outside.

The gate terminal 43 is electrically connected to the gate electrode 10c of the MOSFET 10. The gate terminal 43 is electrically connected to the gate electrode 10c using, for example, the gate metal layer 35 and the bonding wire 44.

The first metal layer 31 is provided on the insulating substrate 30. The first metal layer 31 is electrically connected to the negative terminal N. The first metal layer 31 is electrically connected to the source electrode 10a of the MOSFET 10.

The second metal layer 32 is provided on the insulating substrate 30. The second metal layer 32 is electrically connected to the positive terminal P.

The second metal layer 32 is provided between the MOSFET 10 and the insulating substrate 30. The second metal layer 32 is electrically connected to the drain electrode 10b of the MOSFET 10.

The electrode support member 51 supports, for example, the negative terminal N. The electrode support member 51 is fixed to, for example, the negative terminal N. The negative terminal N and the electrode support member 51 are integrated using, for example, insert molding. The electrode support member 51 may be fixed to, for example, the positive terminal P.

The electrode support member 51 includes the fitting portion 51a. The fitting portion 51a has a protruding shape.

As illustrated in FIG. 19, the electrode support member 51 is fixed to the resin case 24 by fitting the fitting portion 51a into the notch portion 24a provided on the inner side face of the resin case 24.

The fitting portion 51a contains a first resin having a first volume resistivity and a first Young's modulus. The fitting portion 51a is formed of, for example, a first resin. The entire electrode support member 51 may be formed of a first resin.

The first resin is, for example, a polyamide resin or a polybutylene terephthalate resin. The fitting portion 51a is formed of a polyamide resin or a polybutylene terephthalate resin.

The spacer member 52 is provided between the first flat plate portion Np of the negative terminal N and the second flat plate portion Pp of the positive terminal P. The spacer member 52 is fixed to, for example, the negative terminal N. The negative terminal N, the spacer member 52, and the electrode support member 51 are integrated using, for example, insert molding. The spacer member 52 may be fixed to, for example, the positive terminal P.

The spacer member 52 is in contact with, for example, the first flat plate portion Np. The spacer member 52 is in contact with, for example, the second flat plate portion Pp. For example, the spacer member 52 may be separated from the first flat plate portion Np or the second flat plate portion Pp.

The spacer member 52 has a function of electrically insulating the negative terminal N and the positive terminal P from each other. The spacer member 52 has a function of electrically insulating the first flat plate portion Np and the second flat plate portion Pp.

A thickness of the spacer member 52 is, for example, equal to or more than 0.2 mm and equal to or less than 2 mm.

The spacer member 52 contains a second resin having a second volume resistivity and a second Young's modulus. The spacer member 52 is formed of, for example, a second resin.

The second volume resistivity is greater than the first volume resistivity. In addition, the second Young's modulus is greater than the first Young's modulus.

The second resin is, for example, a polyphenylene sulfide resin. The spacer member 52 is formed of, for example, a polyphenylene sulfide resin.

The first resin is, for example, a polyamide resin, and the second resin is, for example, a polyphenylene sulfide resin having a greater volume resistivity and a greater Young's modulus than the polyamide resin. The first resin is, for example, a polybutylene terephthalate resin, and the second resin is, for example, a polyphenylene sulfide resin having a greater volume resistivity and a greater Young's modulus than the polybutylene terephthalate resin.

The third resin contained in the sealing member 53 has a third volume resistivity and a third Young's modulus. The third volume resistivity is, for example, greater than the second volume resistivity. In addition, the third Young's modulus is, for example, lower than the first Young's modulus.

When the first resin is, for example, a polyamide resin and the second resin is, for example, a polyphenylene sulfide resin, the third resin is, for example, a silicone gel having a greater volume resistivity than the polyphenylene sulfide resin and a lower Young's modulus than the polyamide resin.

In addition, when the first resin is, for example, a polybutylene terephthalate resin and the second resin is, for example, a polyphenylene sulfide resin, the third resin is, for example, a silicone gel having a greater volume resistivity than the polyphenylene sulfide resin and a lower Young's modulus than the polybutylene terephthalate resin.

The fourth resin contained in the resin case 24 has a fourth volume resistivity and a fourth Young's modulus. The fourth volume resistivity is, for example, greater than the first volume resistivity. In addition, the fourth Young's modulus is, for example, greater than the first Young's modulus.

The fourth resin contained in the resin case 24 is, for example, the same as the second resin contained in the spacer member 52.

The first resin is, for example, a polyamide resin, and the fourth resin is, for example, a polyphenylene sulfide resin having a greater volume resistivity and a greater Young's modulus than the polyamide resin. When the first resin is, for example, a polybutylene terephthalate resin, the fourth resin is, for example, a polyphenylene sulfide resin having a greater volume resistivity and a greater Young's modulus than the polybutylene terephthalate resin.

According to the power semiconductor module 200 of the second embodiment, similarly to the power semiconductor module 100 of the first embodiment, it is possible to achieve both a reduction in inductance inside the power semiconductor module 200 and a high manufacturing yield of the power semiconductor module 200.

As described above, according to the second embodiment, it is possible to provide a semiconductor device having reduced inductance.

In the first and second embodiments, the case where the number of power semiconductor chips disposed in parallel is three has been described as an example, but the number of power semiconductor chips may be two or equal to or greater than four.

In the first and second embodiments, the case where the power semiconductor module is a “2-in-1” type module and a “1-in-1” type module has been described as an example, but the power semiconductor module may have other circuit configurations such as a “4-in-1” type module, a “6-in-1” type module, and a chopper circuit. In addition, the number of power semiconductor chips may be one.

In the first and second embodiments, the case where the semiconductor chip is a MOSFET has been described as an example, but the semiconductor chip may be another semiconductor chip such as an insulated gate bipolar transistor (IGBT) or a diode.

In the first and second embodiments, the case where the semiconductor layer of the semiconductor chip is the silicon carbide layer has been described as an example, but the semiconductor layer of the semiconductor chip may be, for example, another semiconductor layer such as a nitride semiconductor layer or a silicon layer.

Although some embodiments of the present invention have been described, these embodiments have been presented as examples and are not intended to limit the scope of the invention. These novel embodiments can be implemented in various other forms, and various omissions, substitutions, and modifications can be made without departing from the gist of the invention. For example, a component of one embodiment may be replaced with or modified by a component of another embodiment. These embodiments and modifications thereof are included in the scope and gist of the invention, and are included within the scope of the invention described in the claims and equivalents thereof.

### REFERENCE SIGNS LIST

10 MOSFET (first semiconductor chip)
10a Source electrode (first upper electrode)
10b Drain electrode (first lower electrode)
10x Silicon carbide layer (first semiconductor layer)
11 High-side MOSFET (first semiconductor chip)
11a First source electrode (first upper electrode)
11b First drain electrode (first lower electrode)
11x First silicon carbide layer (first semiconductor layer)
21 Low-side MOSFET (second semiconductor chip)
21a Second source electrode (second upper electrode)
21b Second drain electrode (second lower electrode)
21x Second silicon carbide layer (second semiconductor layer)
24 Resin case (frame body)
30 Insulating substrate
31 First metal layer
32 Second metal layer
33 Third metal layer
51 Electrode support member (first resin member)
51a Fitting portion
52 Spacer member (second resin member)
53 Sealing member (third resin member)
100 Power semiconductor module (semiconductor device)
200 Power semiconductor module (semiconductor device)
N Negative terminal (first electrode terminal)
Np First flat plate portion
P Positive terminal (second electrode terminal)
Pp Second flat plate portion

1. A semiconductor device comprising:
an insulating substrate;
a frame body surrounding the insulating substrate;
a first semiconductor chip including a first upper electrode, a first lower electrode, and a first semiconductor layer provided between the first upper electrode and the first lower electrode, the first semiconductor chip being provided on the insulating substrate;
a first electrode terminal including a first flat plate portion and electrically connected to one of the first upper electrode and the first lower electrode;
a second electrode terminal including a second flat plate portion facing the first flat plate portion and electrically connected to the other of the first upper electrode and the first lower electrode;
a first resin member fixed to at least one of the first electrode terminal and the second electrode terminal and including a fitting portion fitted into the frame body, the fitting portion containing a first resin having a first volume resistivity and a first Young's modulus; and
a second resin member provided between the first flat plate portion and the second flat plate portion and containing a second resin having a second volume resistivity greater than the first volume resistivity and a second Young's modulus greater than the first Young's modulus.

2. The semiconductor device according to claim 1, further comprising a third resin member covering the first semiconductor chip and containing a third resin having a third volume resistivity greater than the second volume resistivity and a third Young's modulus lower than the first Young's modulus.

3. The semiconductor device according to claim 2, wherein the third resin is a silicone gel.

4. The semiconductor device according to claim 1, wherein the frame body contains a fourth resin having a fourth volume resistivity greater than the first volume resistivity and a fourth Young's modulus greater than the first Young's modulus.

5. The semiconductor device according to claim 4, wherein the fourth resin is the same as the second resin.

6. The semiconductor device according to claim 1, wherein the first resin is a polyamide resin, and the second resin is a polyphenylene sulfide resin.

7. The semiconductor device according to claim 1, wherein the first resin is a polybutylene terephthalate resin, and the second resin is a polyphenylene sulfide resin.

8. The semiconductor device according to claim 1, wherein a distance between the first flat plate portion and the insulating substrate is greater than a distance between the second flat plate portion and the insulating substrate, and the first resin member is fixed to the first electrode terminal.

9. The semiconductor device according to claim 1, further comprising:
a first metal layer provided on the insulating substrate and electrically connected to the first electrode terminal; and
a second metal layer provided on the insulating substrate and electrically connected to the second electrode terminal,
wherein the second metal layer is provided between the first semiconductor chip and the insulating substrate, the first upper electrode is electrically connected to the first metal layer, and the first lower electrode is electrically connected to the second metal layer.

10. The semiconductor device according to claim 9, further comprising:
a second semiconductor chip including a second upper electrode, a second lower electrode, and a second semiconductor layer provided between the second upper electrode and the second lower electrode, the second semiconductor chip being provided on the insulating substrate; and
a third metal layer provided on the insulating substrate,
wherein the third metal layer is provided between the second semiconductor chip and the insulating substrate, the second upper electrode is electrically connected to the first metal layer, and the second lower electrode is electrically connected to the third metal layer.

11. The semiconductor device according to claim 1, wherein a distance between the first flat plate portion and the second flat plate portion is equal to or less than 2 mm.

12. The semiconductor device according to claim 1, wherein the first semiconductor layer includes a silicon carbide layer.
